(19) United States
(12) Patent Application Publication
(10) Pub. No.: US 2025/0006472 A1
(43) Pub. Date: Jan. 2, 2025

(54) TREATMENT APPARATUS

(71) Applicant: Ushio Denki Kabushiki Kaisha, Tokyo (JP)

(72) Inventors: Takashi SAWADA, Tokyo (JP); Akinobu NAKASHIMA, Tokyo (JP); Shinji YAMASHITA, Tokyo (JP)

(73) Assignee: Ushio Denki Kabushiki Kaisha, Tokyo (JP)

(21) Appl. No.: 18/752,177

(22) Filed: Jun. 24, 2024

(30) Foreign Application Priority Data
Jun. 28, 2023 (JP) 2023-105787

(51) Int. Cl. H01J 37/32; B08B 5/00; B08B 7/00

(52) U.S. Cl. CPC H01J 37/32715; B08B 5/00; B08B 7/0057; H01J 37/32834; H01J 2237/335

(57) ABSTRACT

Provided is a treatment apparatus that can adjust the atmosphere around a workpiece at an early stage and has high throughput. The treatment apparatus includes: a support base on which a workpiece is placed; a first unit in which the support base is accommodated; a second unit that is disposed adjacent to the first unit and accommodates a discharge part; and a gas inlet through which gas is introduced into the first unit. The first unit and the second unit form a closed space. The second unit emits ultraviolet light or plasma-containing gas generated by the discharge part toward the support base. The support base is configured to enable the workpiece to move in a first direction in which the first unit and the second unit are adjacent to each other, and substantially separates an internal space of the first unit in the first direction.

### CROSS-REFERENCE TO RELATED APPLICATIONS

This application claims priority of Japan Patent Application No. 2023-105787, which was filed on Jun. 28, 2023, and which is incorporated herein in its entirety by reference.

### BACKGROUND OF THE INVENTION

### Field of the Invention

The present invention particularly relates to a treatment apparatus that performs a cleaning treatment or the like for an object to be treated (workpiece) in a predetermined gas atmosphere.

### Description of the Related Art

Conventionally, as a technique for performing cleaning or surface treatment of a workpiece, a technique for irradiating a workpiece with ultraviolet light or exposing a workpiece to a gas containing plasma (hereinafter simply referred to as “plasma-containing gas”) is known (cf. Patent Document 1 and Patent Document 2 below).

### PRIOR ART DOCUMENT

### Patent Document

Patent Document 1: JP-A-2003-144913
Patent Document 2: JP-A-2002-320845

### SUMMARY OF THE INVENTION

Patent Document 1 describes a treatment apparatus (also called a “light treatment apparatus”) that irradiates a workpiece with vacuum ultraviolet light having a wavelength of 200 nm or less. Higher oxygen concentration in a treatment chamber where the workpiece is located causes that the workpiece cannot be irradiated with the amount of ultraviolet light necessary for treatment, and desired treatment may not be performed. Because the vacuum ultraviolet light is absorbed by oxygen. In view of this, in the light treatment apparatus, an inert gas such as nitrogen gas is introduced into the treatment chamber, and the oxygen concentration around the workpiece is maintained within a predetermined range.

The thickness of the workpiece to be treated varies. Different workpiece thicknesses change the distance between a light source emitting the ultraviolet light and the workpiece. Therefore, to adjust conditions for irradiation of the workpiece with the ultraviolet light, the light treatment apparatus is configured to enable the workpiece to move in a direction in which the workpiece and the light source face each other.

In particular, for a workpiece with a large thickness, it is necessary to increase the separation distance between a support base on which the workpiece is placed and the light source. In view of this, the treatment chamber of the light treatment apparatus has a sufficient length in the direction in which the workpiece and the light source face each other. As a result, the volume of the treatment chamber increases.

When the volume of the treatment chamber is large, even if a workpiece with a small thickness is treated, a long time is required for replacement around the workpiece with an inert gas or the like. For this reason, the conventional treatment apparatus has faced an issue with low throughput.

In addition, Patent Document 2 describes a plasma treatment apparatus that applies high voltage between electrodes to generate plasma and exposes a workpiece to plasma-containing gas to treat the workpiece. The same issue as above is also pointed out for such a plasma treatment apparatus.

That is, in the plasma treatment apparatus, to perform desired plasma treatment for the workpiece, the separation distance between the workpiece and the electrode that generates plasma is defined according to the thickness of the workpiece. Further, to adjust the treatment condition of the workpiece, a predetermined process gas is introduced to adjust the atmosphere around the workpiece. Here, when the volume of the treatment chamber is increased to enable to adjustment the position of the workpiece, a long time is required to adjust the atmosphere around the workpiece by introducing the process gas. This results in reduced throughput of the plasma treatment apparatus.

In view of the above problems, an object of the present invention is to provide a treatment apparatus that can adjust the atmosphere around a workpiece at an early stage and has high throughput.

A treatment apparatus according to the present invention includes: a support base on which a workpiece is placed; a first unit in which the support base is accommodated; a second unit that is disposed adjacent to the first unit and accommodates a discharge part including a discharge lamp or a plasma generator; and a gas inlet through which gas is introduced into the first unit. The first unit and the second unit form a closed space. The second unit emits ultraviolet light or plasma-containing gas generated by the discharge part toward the support base. The support base is configured to enable the workpiece to move in a first direction in which the first unit and the second unit are adjacent to each other, and substantially separates an internal space of the first unit in the first direction.

With the above configuration, the internal space of the first unit (treatment chamber) where the workpiece is positioned is substantially separated into: a space where the workpiece is positioned (hereinafter referred to as a “treatment space” for convenience); and a space located on the side opposite to the treatment space, across from the workpiece (hereinafter referred to as a “non-treatment space” for convenience). The term “substantially separated” herein means that the area of a path communicating the treatment space and the non-treatment space is 10% or less of the area of the treatment space, when viewed in the first direction.

In the above configuration, since the treatment space and the non-treatment space are substantially separated, the atmosphere around the workpiece can be adjusted by simply introducing a predetermined gas through the gas inlet to adjust the atmosphere of the treatment space. That is, it is not necessary to adjust the atmosphere of the entire treatment chamber to adjust the atmosphere around the workpiece. Thereby, the atmosphere around the workpiece can be adjusted at an early stage, resulting in improved throughput of the treatment apparatus.

With the above configuration, the amount of gas required to adjust the atmosphere around the workpiece is reduced. That is, the above configuration also has an effect of reducing the cost required for the treatment of the workpiece and the environmental load.

In the treatment apparatus, the support base may include a first member that supports the workpiece, and a second member that substantially separates the internal space of the first unit in the first direction.

From the viewpoint of easier substantial separation of the internal space of the first unit, it is preferable to provide the support base with a second member that is different to the first member. Depending on the treatment required for the workpiece, the workpiece may be heated or cooled, for example, during the treatment of the workpiece. In such a case, a heater, a flow path through which cooling water flows, and the like are installed in the first member, and hence the configuration of the first member tends to be complicated. In contrast, the above configuration enables easy substantial separation of the internal space of the first unit without significantly changing the design of the first member.

The second member may be in contact with the main surface of the first member on the side opposite to the second unit.

With the above configuration, when the first member is moved to move the workpiece, the second member is also moved together with the first member. That is, the size of the treatment space, where the atmosphere needs adjustment, is adjusted according to the thickness of the workpiece, and hence the above configuration is preferable. From the same viewpoint, the second member may be in contact with the side surface of the first member.

In the above treatment apparatus, the support base may include a third member configured to support the second member and to move the second member and the first member in the first direction.

The first unit may have a gas outlet, through which an atmospheric gas in the first unit is exhausted to an outside, at a location on a side opposite to the second unit in the first direction with reference to the second member.

It is preferable to stabilize the atmosphere around the workpiece in the treatment space during the treatment of the workpiece. With the above configuration, the gas introduced into the first unit through the gas inlet passes through the treatment space and is exhausted from the non-treatment space. Here, since the treatment space and the non-treatment space are substantially separated, it is difficult for the gas to move from the non-treatment space side to the treatment space side. Therefore, the atmosphere in the treatment space is easily stabilized, and the above configuration is preferable.

The second member may be configured to be expandable and contractible in a direction parallel to the main surface of the first member.

The term “main surface” herein refers to one of surfaces constituting a plate-shaped object and having a much larger area than other surfaces. From the viewpoint of accurately adjusting the oxygen concentration and the like of the treatment space, the path communicating the treatment space and the non-treatment space is preferably narrower. However, if the path is narrow, when the second member is moved in the first direction to adjust the position of the workpiece, there is a greater concern that the second member may collide with the wall surface of the first unit due to vibration or the like. In contrast, with the above configuration, after the position of the first member is adjusted, the second member is expanded in the direction parallel to the main surface of the first member, so that the path communicating the treatment space and the non-treatment space can be narrowed.

The discharge part may include a discharge lamp and have a light extraction window through which ultraviolet light emitted from the discharge lamp is extracted toward the first unit, and the first unit and the second unit may be spatially separated. The discharge part may include a plasma generator, and the first unit and the second unit may spatially communicate with each other.

According to the present invention, there is provided a treatment apparatus that can adjust an atmosphere around a workpiece at an early stage and has high throughput.

### BRIEF DESCRIPTION OF THE DRAWINGS

FIG. 1 is a view schematically illustrating a structure of an embodiment of a treatment apparatus according to the present invention;

FIG. 2 is a plan view of a first unit when viewed from a +Z direction;

FIG. 3 is a graph illustrating results of verification;

FIG. 4 is a view illustrating a modification of the treatment apparatus 1 following FIG. 1;

FIG. 5 is a view illustrating another modification of the treatment apparatus;

FIG. 6 is a view illustrating still another modification of the treatment apparatus;

FIG. 7 is a view illustrating another configuration example of the support base;

FIG. 8 is a view illustrating still another configuration example of the support base; and

FIG. 9 is a view illustrating another configuration example of the first unit.

### DETAILED DESCRIPTION OF THE PREFERRED EMBODIMENT

An embodiment of a treatment apparatus according to the present invention will be described with reference to the drawings as appropriate. Note that the following drawings are all schematically illustrated, and the actual dimensional ratios are not necessarily the same as the dimensional ratios in the drawings. Further, the dimensional ratios are not necessarily the same among the drawings.

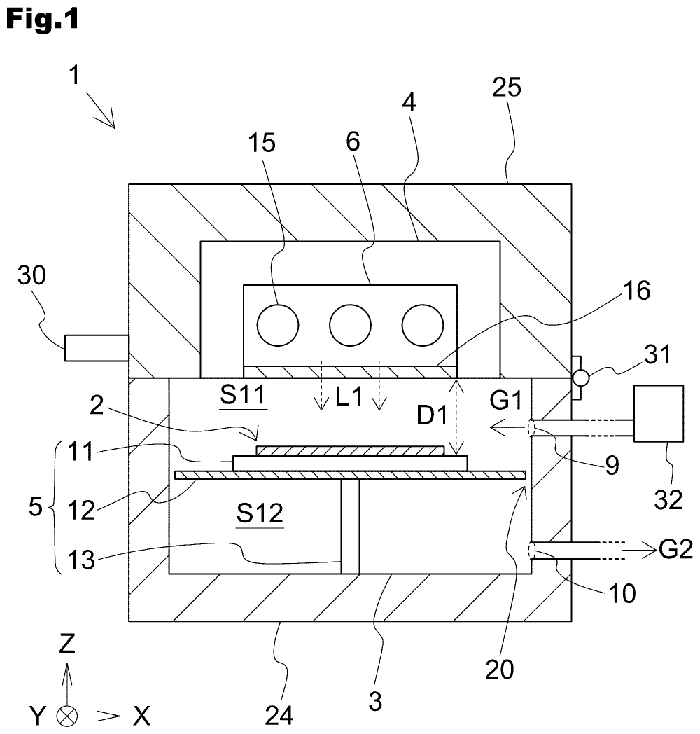

FIG. 1 is a view schematically illustrating a structure of an embodiment of the treatment apparatus according to the present invention. As illustrated in FIG. 1, the treatment apparatus 1 includes a first unit 3 in which a workpiece 2 to be treated is accommodated, and a second unit 4.

The following drawings will be described with appropriate reference to an X-Y-Z coordinate system, with a direction in which the first unit 3 and the second unit 4 are adjacent to each other defined as the Z direction, and a plane orthogonal to the Z direction defined as the XY plane. The Z direction corresponds to a “first direction”, and is typically the vertical direction.

In the following description, when positive and negative directions are distinguished at the time of expressing directions, the directions are described with a positive or negative symbol, such as a “+X direction” or a “−X direction”. When the direction is expressed without distinguishing between positive and negative direction, the direction is simply described as the “X direction”. Namely, in the present specification, when the direction is simply described as the “X direction”, both the “+X direction” and the “−X direction” are included. The same applies to the Y direction and the Z direction.

The first unit 3 is accommodated in the lower cover 24, and the second unit 4 is accommodated in a top cover 25 (cf. FIG. 1). For example, by an operator (not illustrated) operating a handle 30, the top cover 25 is rotated against a lower cover 24 via a hinge 31. In a state where the top cover 25 is closed, the first unit 3 and the second unit 4 form a closed space.

In the present embodiment, the workpiece 2 is irradiated with ultraviolet light L1 generated by the second unit 4. First, the configuration of the second unit 4 will be described.

The second unit 4 accommodates a discharge part 6 (cf. FIG. 1). The discharge part 6 includes a discharge lamp 15 that emits the ultraviolet light L1 and a light extraction window 16 that extracts the ultraviolet light L1 toward the first unit 3.

The discharge lamp 15 emits the ultraviolet light L1. The ultraviolet light L1 typically has a peak wavelength of 200 nm or less (The ultraviolet light L1 is also called “vacuum ultraviolet light”). The discharge lamp 15 is, for example, an excimer lamp in which a xenon (Xe) gas is sealed as a main luminescent gas. Note that the type of the luminescent gas of the excimer lamp is appropriately selected according to the wavelength of the ultraviolet light. As an example, the combination of respective luminescent gases with their peak wavelengths is as follows: Xe (172 nm), Kr (146 nm), ArF (193 nm), and ArBr (165 nm).

The light extraction window 16 is made of a material that transmits the ultraviolet light L1, such as synthetic fused silica. Note that the phrase “transmits the ultraviolet light L1” means that the transmittance to the ultraviolet light L1 is 80% or more. In the present embodiment, the first unit 3 and the second unit 4 are spatially separated.

The first unit 3 accommodates a support base 5 on which the workpiece 2 is placed. As illustrated in FIG. 1, the support base 5 includes a first member 11 on which the workpiece 2 is placed, a second member 12 in contact with the −Z side main surface of the first member 11, and a third member 13 that supports the first member 11 and the second member 12.

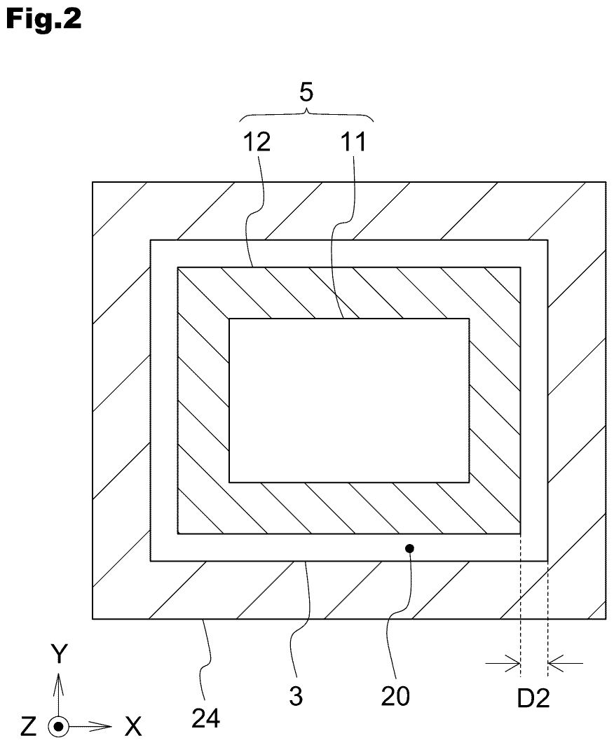

FIG. 2 is a plan view when the first unit 3 is viewed from the +Z direction in a state where the top cover 25 of the treatment apparatus 1 is opened. In FIG. 2, the workpiece 2 is not illustrated. As illustrated in FIG. 2, the second member 12 is located outside the first member 11 when viewed from the +Z direction.

The second member 12 substantially separates the internal space of the first unit 3 into: a space S11 (hereinafter referred to as a “treatment space S11”) on the side where the workpiece 2 is positioned; and a space S12 (hereinafter referred to as a “non-treatment space S12”) on the side opposite to the treatment space S11 via the second member 12 (cf. FIG. 1). More specifically, as illustrated in FIG. 2, the area of a path 20 communicating the treatment space S11 and the non-treatment space S12, when viewed in the Z direction, is 10% or less of the area of the treatment space S11. In other words, the ratio of the area of the support base 5 to the area of the treatment space S11, when viewed from the +Z direction, is 90% or more.

As an example, a width D2 of the path 20 is preferably 5 mm or less, and more preferably 1 mm or less.

The first member 11 and the second member 12 are preferably made of a metal material such as aluminum or stainless steel in view of durability against the ultraviolet light L1, radiant heat from the discharge lamp 15, and ozone, which will be described later. For example, hard anodized aluminum is a suitable example of the metal material. The first member 11 and the second member 12 may be made of the same material or different materials. Note that the first member 11 may be configured to heat the workpiece 2 by being heated by a heating mechanism (not illustrated).

The third member 13 is configured to enable the workpiece 2, placed on the first member 11 to move in the Z direction. More specifically, the third member 13 can adjust a distance D1 between the +Z-side main surface of the first member 11 and the light extraction window 16 (cf. FIG. 1). The third member 13 can be of any configuration as long as the position of the workpiece 2 in the Z direction can be changed. For example, the first member 11 may be made movable in the Z direction by driving a motor or the like, or the position of the first member 11 in the Z direction may be made changeable by manual work.

The first unit 3 has a gas inlet 9, through which a predetermined process gas G1 is introduced from any gas reservoir 32 into the treatment space S11, and a gas outlet 10, through which a gas G2 in the treatment space S11 and the non-treatment space S12 are exhausted to the outside. In the present embodiment, the gas outlet 10 is provided at a location on the −Z side of the second member 12. From the viewpoint of preventing the gas in the non-treatment space S12 from moving towards the treatment space S11 side, the gas outlet 10 is preferably located on the −Z side of the second member 12.

In FIG. 1, the gas inlet 9 and the gas outlet 10 are illustrated as being provided on the same +X side wall surface in the first unit 3, but this is only an example. For example, the gas outlet 10 may be provided on the −X side wall surface, or may be provided on the +Y side wall surface, the −Y side wall surface, or the −Z side wall surface (bottom surface). That is, the gas inlet 9 and the gas outlet 10 may be provided on the same wall surface or may be provided on different wall surfaces. Furthermore, the gas inlet 9 and the gas outlet 10 may be provided at a plurality of locations.

The discharge lamp 15 is turned on to irradiate the workpiece 2 with the ultraviolet light L1, thereby performing cleaning and surface treatment on the workpiece 2. More specifically, the irradiation of the workpiece 2 with the ultraviolet light L1 decomposes organic molecules on the surface of the workpiece 2 or generates a hydrophilic functional group on the surface of the workpiece 2.

Here, when the ultraviolet light L1 is absorbed by oxygen in the treatment space S11, desired treatment cannot be executed on the workpiece 2. In view of this, the process gas G1 with a low oxygen concentration is introduced through the gas inlet 9 of the first unit 3, and the oxygen concentration in the treatment space S11 is reduced. For example, the process gas G1 is an inert gas such as nitrogen.

At this time, it takes some time from the start of the supply of the process gas G1 until the atmosphere around the workpiece 2 becomes a desired atmosphere. However, in the present embodiment, as described above, the support base 5, more specifically, the second member 12 of the support base 5, substantially separates the internal space of the first unit 3 into the treatment space S11 and the non-treatment space S12. Therefore, the adjustment of the atmosphere around the workpiece 2 is completed at an early stage.

This means that the time required to open the top cover 25, place the workpiece 2 in the first unit 3, close the top cover 25, and complete the adjustment of the atmosphere around the workpiece 2 is reduced. This leads to improved throughput of the treatment apparatus 1.

Whether or not the adjustment of the atmosphere around the workpiece 2 has been completed can be determined, for example, by checking the oxygen concentration of an oxygen concentration sensor (not illustrated) installed in the treatment space S11.

To adjust the atmosphere around the discharge lamp 15, the second unit 4 may have a gas inlet (not illustrated) through which a predetermined gas is introduced into the second unit 4, the gas inlet being different from the gas inlet 9. For example, an inert gas such as nitrogen may be introduced into the second unit 4 to reduce the oxygen concentration around the discharge lamp 15, with a view to preventing the absorption of the ultraviolet light L1 into oxygen present around the discharge lamp 15.

### [Verification]

It has been verified that the time required for adjusting the atmosphere around the workpiece 2 can be reduced by substantially separating the internal space of the first unit 3 into the treatment space S11 and the non-treatment space S12, which will be described below.

This verification was executed using a treatment apparatus 1, configured as described with reference to FIGS. 1 and 2. In this verification, a measurement was performed of the time required from the start of introducing nitrogen gas with a purity of 99.99% into gas inlet 9 at a flow rate of 100 L per minute until the oxygen concentration in the treatment space S11 reached 0.1%.

### Example 1

Detailed conditions in Example 1 are as follows.

The cross-sectional area on the XY plane of the first unit 3: 2500 cm²

The distance D1 between the +Z side main surface of the first member 11 and the light extraction window 16 (cf. FIG. 1): 100 mm

The width D2 (cf. FIG. 2) of the path 20 communicating the treatment space S11 and the non-treatment space S12: 2 mm

### Example 2

This example was performed under the same conditions as Example 1, with the exception that the distance D1 was set to 67 mm.

### Example 3

This example was performed under the same conditions as Example 1, with the exception that the distance D1 was set to 34 mm.

### Reference Example 1

This reference example was performed under the same conditions as Example 1, with the exception that the second member 12 was removed under the conditions of Example 1. That is, in Reference Example 1, the treatment space S11 and the non-treatment space S12 are not substantially separated. More specifically, in Reference Example 1, the distance between the first member 11 and the wall surface of the first unit 3 was set to 75 mm (cf. FIG. 2).

### [Results of Verification]

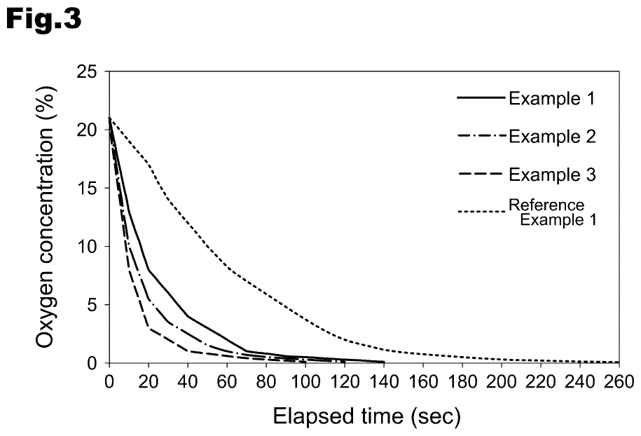

FIG. 3 is a graph illustrating the results of this verification. In FIG. 3, the horizontal axis represents the elapsed time from the start of introducing the nitrogen gas, and the vertical axis represents the oxygen concentration in the treatment space S11. As illustrated in FIG. 3, in Reference Example 1, it took about 150 seconds for the oxygen concentration to fall below 1%. Further, in Reference Example 1, it took about 250 seconds for the oxygen concentration to decrease to about 0.1%.

In contrast, in Example 1, the oxygen concentration fell below 1% in about 70 seconds, and the oxygen concentration decreased to 0.1% in about 140 seconds. As described above, in Example 1, it is presumed that the oxygen concentration in the treatment space S11 was reduced in a shorter time than in Reference Example 1 because the first unit 3 was substantially separated into the treatment space S11 and the non-treatment space S12 by the second member 12.

That is, by introducing the nitrogen gas into the treatment space S11 with the path 20 narrowed, the pressure in the treatment space S11 becomes higher than the pressure in the non-treatment space S12. Therefore, it is considered that the gas in the treatment space S11 flowed to the non-treatment space S12 while the gas in the non-treatment space S12 was less likely to flow to the treatment space S11, consequently enabling the oxygen concentration in the treatment space S11 to be reduced at an early stage.

In contrast, in Reference Example 1, the distance between the first member 11 and the wall surface of the first unit 3 is as large as 75 mm, and the gas closer to the −Z side than the first member 11 flows more easily to the workpiece 2 side. Therefore, in Reference Example 1, it is considered that a long time was required for the oxygen concentration around the workpiece 2 to decrease.

According to Example 2 and Example 3, as the distance D1 between the first member 11 and the light extraction window 16 decreased, the time required for decreasing the oxygen concentration in the treatment space S11 decreased. That is, it can be understood that the size of the treatment space S11 where the atmosphere needs adjustment is adjusted according to the distance between the workpiece 2 and the light extraction window 16.

According to this verification, it can be understood that the time required for adjusting the atmosphere around the workpiece 2 is reduced by substantially separating the first unit 3 into the treatment space S11 and the non-treatment space S12. That is, the above embodiment provides the treatment apparatus 1 that can adjust the atmosphere around the workpiece 2 at an early stage and has high throughput.

### Modifications

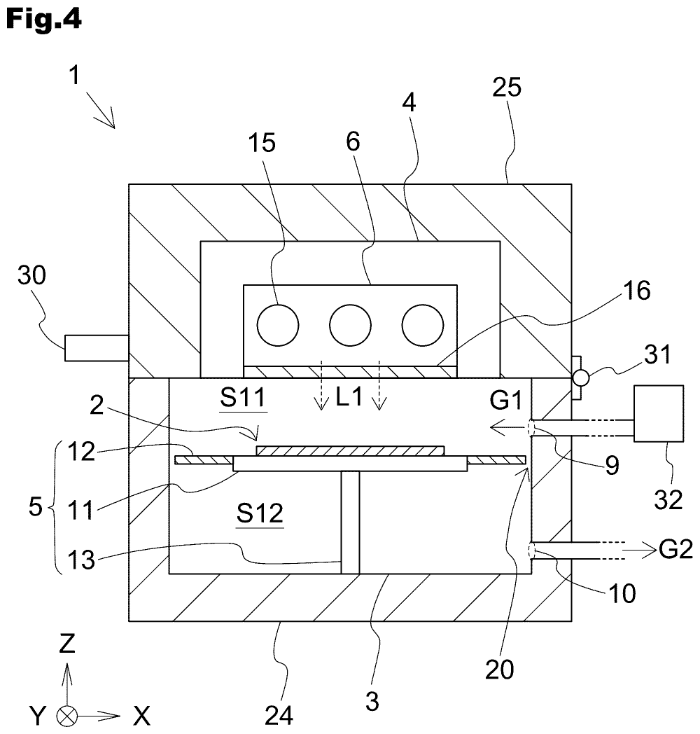

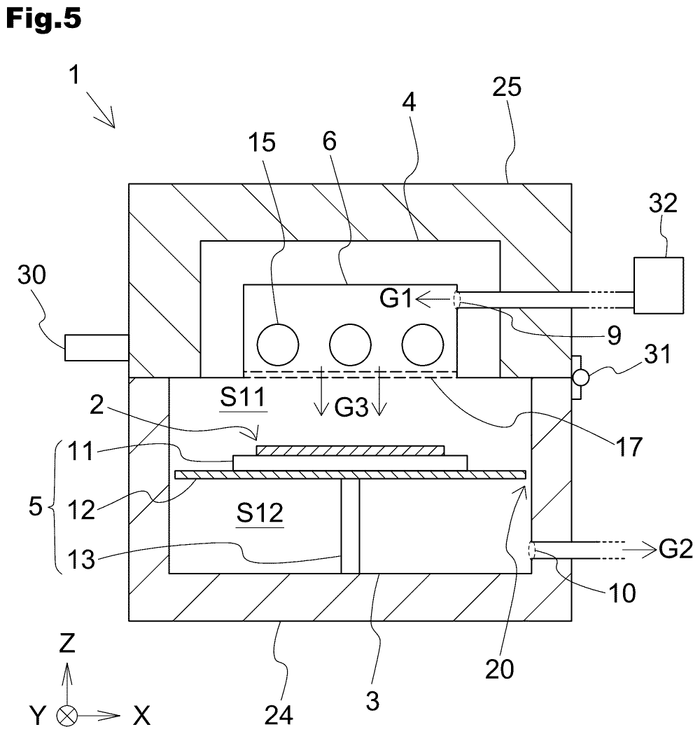

Modification of the treatment apparatus 1 will be described below with reference to the drawings, focusing on differences from the above embodiment.
<1> FIG. 4 is a view illustrating a modification of the treatment apparatus 1 in accordance with FIG. 1. As illustrated in FIG. 4, the second member 12 may be configured to be in contact with the side surface of the first member 11 and extend in a direction away from the first member 11. In this case, the third member 13 supports the first member 11. In the present modification, less material is required to construct the second member 12 than in the above embodiment. That is, the cost and the like for constituting the treatment apparatus 1 are reduced, and hence the present modification is preferable.
<2> FIG. 5 is a view illustrating another modification of the treatment apparatus 1. In the above, it has been described that the first unit 3 and the second unit 4 are spatially separated. However, as illustrated in FIG. 5, a light extraction surface 17 having an opening may be formed on the −Z-side surface of the second unit 4, and the first unit 3 and the second unit 4 may spatially communicate with each other.

In the present modification, the gas inlet 9 is provided in the second unit 4 from the viewpoint of adjusting the internal space of the second unit 4 and the atmosphere of the treatment space S11. For example, by turning on the discharge lamp 15 with the oxygen concentration in both spaces adjusted, an ozone-containing gas G3 can be generated in the space and provided for the treatment of the workpiece 2.

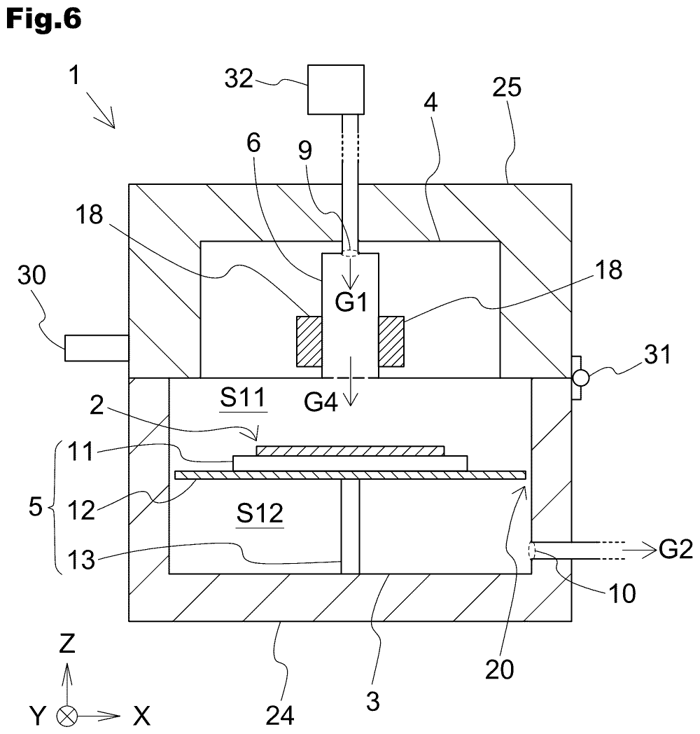

In the present modification, similarly to the above embodiment, the time required to adjust the atmosphere around the workpiece 2 is reduced by substantial separation of the first unit 3.
<3> FIG. 6 is a view illustrating still another modification of the treatment apparatus 1. In the above, it has been described that the discharge part 6 includes the discharge lamp 15, but as illustrated in FIG. 6, the discharge part 6 may include a plasma generator including a pair of electrodes 18.

In the present modification, the same argument as described with reference to FIG. 5 can be made on the point that the gas inlet 9 is provided in the second unit 4.

In the present modification, a plasma-containing gas G4 is generated by applying an alternating-current high voltage to the process gas G1, which contains a plasma source such as nitrogen or argon, via the pair of electrodes 18. Then, the treatment of the workpiece 2 is performed by exposing the plasma-containing gas G4 onto the workpiece 2. More specifically, the plasma-converted active species contained in the plasma-containing gas G4 cleaves the chemical bond of the organic molecule on the workpiece 2. As a result, the organic contaminants on the workpiece 2 are removed, or a hydrophilic functional group is formed on the surface of the workpiece 2.

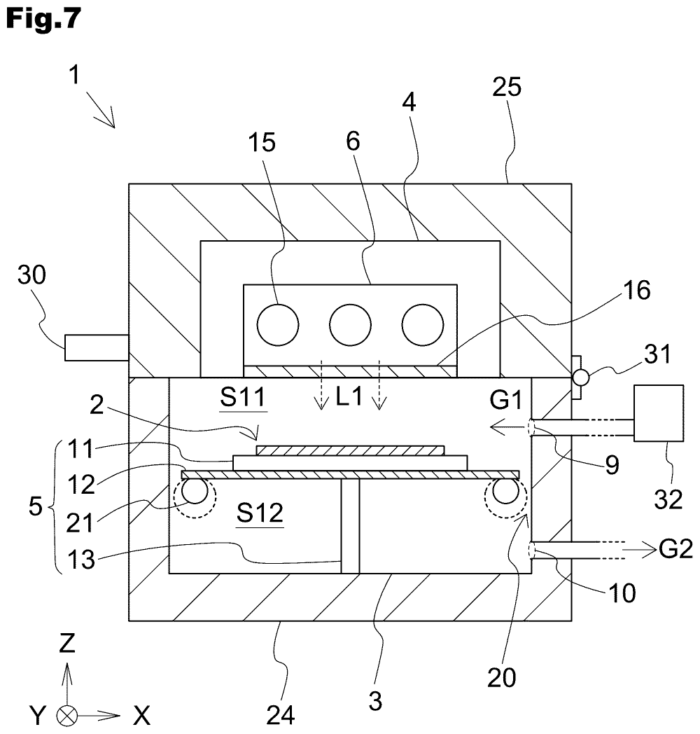

Here, to perform desired treatment for the workpiece 2, the atmosphere around the workpiece 2 is adjusted using the process gas G1 before a high voltage is applied to the electrode 18. In the present modification as well, similarly to the above embodiment, the atmosphere around the workpiece 2 can be adjusted in a short time by substantial separation of the first unit 3.
<4> The second member 12 of the support base 5 has any shape as long as the internal space of the first unit 3 is substantially separated. FIG. 7 is a view illustrating another configuration example of the support base 5. For example, as illustrated in FIG. 7, the second member 12 may be configured to include an expansion/contraction part 21 on the peripheral edge of the −Z-side surface, and may be configured to be expandable and contractible in a direction parallel to the main surface of the first member 11.

The expansion/contraction part 21 of the second member 12 is constructed of a tube made of a rubber material such as fluoro rubber or silicone rubber. As illustrated in FIG. 7, the +Z-side surface of the expansion/contraction part 21 is fixed. By feeding any gas into the expansion/contraction part 21, the expansion/contraction part 21 is expanded in the −Z direction and the X direction. In FIG. 7, a dashed line indicates the expansion/contraction part 21 in a state where the gas has been fed. The expansion/contraction part 21 can be contracted by discharging the fed gas.

Note that FIG. 7 is a cross-sectional view of the treatment apparatus 1 when viewed in the Y direction, but when viewed in the X direction, the expansion/contraction part 21 expands/contracts in the −Z direction and the Y direction. That is, the expansion/contraction part 21 is expandable and contractible in a direction parallel to the XY plane.

From the viewpoint of accurately adjusting the oxygen concentration and the like of the treatment space S11, the path 20 communicating the treatment space S11 and the non-treatment space S12 is preferably narrower. However, if the path 20 is narrow, when the second member 12 is moved in the Z direction to adjust the position of the workpiece 2, there is a greater concern that the second member 12 may collide with the wall surface of the first unit 3 due to vibration or the like. In contrast, since the second member 12 includes the expansion/contraction part 21, the path 20 can be narrowed by expanding the expansion/contraction part 21 after the adjustment of the position of the workpiece 2.

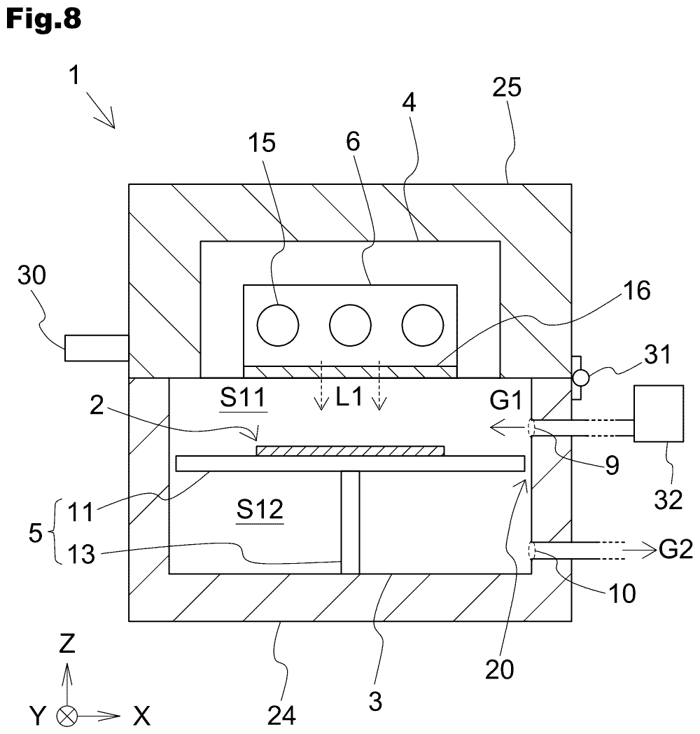

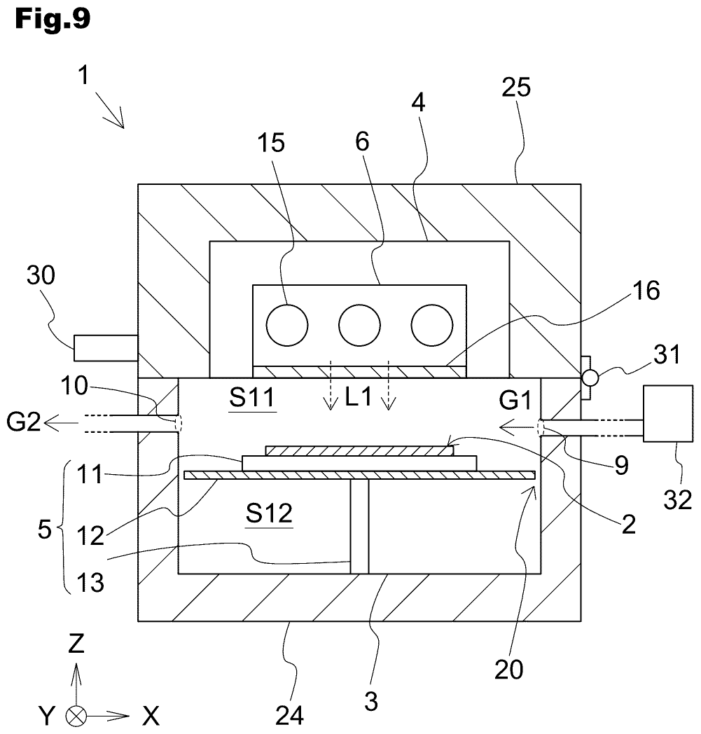

For example, the peripheral edge of the second member 12 may be foldable. In this case, switching between the folded state and the unfolded state of the peripheral edge enables the second member 12 to expand and contract in the XY plane.
<5> FIG. 8 is a view illustrating still another configuration example of the support base 5. In the above, it has been described that the second member 12 substantially separates the internal space of the first unit 3, but as illustrated in FIG. 8, the first member 11 may substantially separate the internal space of the first unit 3.
<6> FIG. 9 is a view illustrating another configuration example of the first unit 3. In the above, it has been described that the gas outlet 10 is provided in the non-treatment space S12, but in the present invention, the gas outlet 10 is located at any position. For example, as illustrated in FIG. 9, the gas outlet 10 may be provided at a certain location on the +Z side of the second member 12 and located in the treatment space S11. The gas outlet 10 may be provided in both the treatment space S11 and the non-treatment space S12.

As illustrated in FIG. 9, even when the gas outlet 10 is provided on the +Z side of the second member 12, it is presumed that the first unit 3 is substantially separated into the treatment space S11 and the non-treatment space S12, so that the time required for adjusting the atmosphere of the treatment space S11 is reduced.

From the viewpoint of preventing the gas in the non-treatment space S12 from convecting and flowing into the area around the workpiece 2, it is preferable to configure the second member 12 to be expandable and contractible with respect to the XY plane, as described with reference to FIG. 7. That is, when the process gas G1 is introduced into the treatment space S11, it is preferable to close the path 20 or narrow the path 20 by expanding the second member 12 to come into contact with the wall surface of the first unit 3. The gas in the non-treatment space S12 is prevented from flowing into the area around the workpiece 2, and as a result, the atmosphere around the workpiece 2 can be adjusted at even an earlier stage.
<7> The above embodiment and modifications can be realized in combination as appropriate.

What is claimed is:

1. A treatment apparatus comprising:
a support base on which a workpiece is placed;
a first unit in which the support base is accommodated;
a second unit that is disposed adjacent to the first unit and accommodates a discharge part including a discharge lamp or a plasma generator; and
a gas inlet through which gas is introduced into the first unit, wherein
the first unit and the second unit form a closed space,
the second unit emits ultraviolet light or plasma-containing gas generated by the discharge part toward the support base, and
the support base is configured to enable the workpiece to move in a first direction in which the first unit and the second unit are adjacent to each other, and substantially separates an internal space of the first unit in the first direction.

2. The treatment apparatus according to claim 1, wherein the support base includes
a first member that supports the workpiece, and
a second member that substantially separates the internal space of the first unit in the first direction.

3. The treatment apparatus according to claim 2, wherein the second member is in contact with a main surface of the first member on a side opposite to the second unit.

4. The treatment apparatus according to claim 2, wherein the second member is in contact with a side surface of the first member.

5. The treatment apparatus according to claim 3, wherein the support base includes a third member configured to support the second member and to move the second member and the first member in the first direction.

6. The treatment apparatus according to claim 2, wherein the first unit has a gas outlet, through which an atmospheric gas in the first unit is exhausted to an outside, at a location on a side opposite to the second unit in the first direction with reference to the second member.

7. The treatment apparatus according to claim 2, wherein the second member is configured to be expandable and contractible in a direction parallel to a main surface of the first member.

8. The treatment apparatus according to claim 1, wherein
the discharge part includes a discharge lamp and has a light extraction window through which ultraviolet light emitted from the discharge lamp is extracted toward the first unit, and
the first unit and the second unit are spatially separated.

9. The treatment apparatus according to claim 1, wherein
the discharge part includes a plasma generator, and
the first unit and the second unit spatially communicate with each other.
